(19) United States
(12) Patent Application Publication
(10) Pub. No.: US 2025/0079337 A1
(43) Pub. Date: Mar. 6, 2025

(54) INTEGRATED CIRCUITS WITH TWO-SIDE METALLIZATION AND EXTERNAL STIFFENING LAYER AND RELATED FABRICATION METHODS

(71) Applicant: QUALCOMM Incorporated, San Diego, CA (US)

(72) Inventors: Xia Li, San Diego, CA (US); Jonghae Kim, San Diego, CA (US); Bin Yang, San Diego, CA (US); Giridhar Nallapati, San Diego, CA (US)

(21) Appl. No.: 18/460,863

(22) Filed: Sep. 5, 2023

(51) Int. Cl. H01L 23/00; H01L 21/768; H01L 23/48; H01L 23/522

(52) U.S. Cl. CPC H01L 23/562; H01L 21/76898; H01L 23/481; H01L 23/5226; H10D 1/68

(57) ABSTRACT

An integrated circuit (IC) includes a plurality of first metallization layers on a front side of a circuit layer and a plurality of second metallization layers on a back side of the circuit layer. A semiconductor substrate on the back side of the circuit layer of the IC is thinned to improve access to devices from the back side. The plurality of second metallization layers are employed to provide increased interconnection among the devices without increasing area and may provide increased access to external contacts. Thinning the semiconductor substrate reduces structural rigidity needed for processing, so the IC also includes a stiffening layer on one of the plurality of first metallization layers and the plurality of second metallization layers to increase rigidity and first vias extending through the stiffening layer to couple to first contacts.

### BACKGROUND

### I. Field of the Disclosure

The technology of the disclosure relates generally to integrated circuits (ICs) and, more particularly, to ICs with metallization layers on both sides.

### II. Background

Integrated circuits are based on circuit layers of transistors formed in one side of a semiconductor (e.g., silicon) substrate. Circuits are formed by connecting the transistors to each other and to external circuit contacts using metal interconnects in metallization layers that are formed on the circuit layer. The metallization layers include several metal layers that are substantially parallel to the circuit layer. Thus, the interconnects in these layers may be referred to as “horizontal.” The metal layers are separated in the “vertical” direction by a dielectric material and horizontal interconnects in different metal layers can be connected by vertical interconnect accesses (“vias”) that extend through the dielectric material. Spaces between the horizontal interconnects in the metal layers are also filled by the dielectric material. These interconnects can provide data signals, control signals, and power signals to the transistors. Because the pitch of transistors is small and continues to get smaller with advances in technology, the metal interconnects closest to the circuit layer also must be small but increase in size in the metal layers farther from the circuit layer, which limits the capacity for interconnection of the transistors. In addition, the metal layers may couple to even larger input/output (I/O) contacts on a top surface of the metallization layers. The I/O contacts may be efficiently arranged in arrays but, due to minimum contact sizes and minimum separation pitches, a limited number of contacts can fit on the top surface. Due to the need for more I/O contacts, some manufacturers of ICs have created through-silicon vias (TSVs) from the circuit layer through the semiconductor substrate to a back side of the IC. However, such TSVs can be large in cross-section and occupy areas of the circuit layer, known as “keep-out zones” in which no transistors can be formed. Thus, the number of such TSVs can be limited or can cause the size of an IC to be increased. Solutions are needed for providing sufficient numbers of I/O contacts on an IC as the numbers of transistors in a circuit layer continues to increase.

### SUMMARY

Aspects disclosed herein include integrated circuits (ICs) with two-side metallization and external stiffening layers. Related methods of fabricating an IC with two-side metallization and external stiffening layers are also disclosed. An exemplary IC includes first metallization layers on a first, front side of a circuit layer and second metallization layers on a second, back side of the circuit layer. A semiconductor substrate on the second, back side of the circuit layer can be thinned to improve access to the second, back side of devices in the circuit layer. In this regard, the second metallization layers can provide increased interconnection between devices in the circuit layer and may provide increased access to the circuit layer from external contacts for data, control, and power signals. However, thinning a semiconductor substrate including the circuit layer may significantly reduce structural rigidity needed for processing. Thus, the exemplary IC also includes a stiffening layer on one of the first metallization layers and the second metallization layers and first vias extending through the stiffening layer to first contacts. The stiffening layer provides structural rigidity to reduce mechanical and electrical failures caused by flexing of the circuit layer during, for example, manufacturing processes. In some examples, the first metallization layers include front side metallization layers, and the second metallization layers include back side power rails and back side metallization layers. In some examples, the IC also includes second contacts on the metallization layers opposite to the stiffening layer. In this regard, electrical connections between the first contacts and the second contacts may be provided and the IC may be employed as a bottom or intermediate IC in a stack of ICs on a package substrate in an IC package.

In an exemplary aspect, an IC is disclosed. The IC includes a circuit layer and a plurality of first metallization layers disposed on a first side of the circuit layer and coupled to the circuit layer. The IC also includes a plurality of second metallization layers disposed on a second side of the circuit layer opposite to the first side and coupled to the circuit layer and a stiffening layer disposed on one of the plurality of first metallization layers and the plurality of second metallization layers. The IC further includes a first via extending through the stiffening layer to couple the one of the plurality of first metallization layers and the plurality of second metallization layers to a first contact on the stiffening layer.

In another exemplary aspect, a method of fabricating an integrated circuit (IC) is disclosed. The method includes forming a circuit layer and forming a plurality of first metallization layers on a first side of the circuit layer. The method also includes forming a plurality of second metallization layers on a second side of the circuit layer opposite to the first side and disposing a stiffening layer on one of the plurality of first metallization layers and the plurality of second metallization layers. The method further includes forming a first via extending through the stiffening layer from a first side of the stiffening layer adjacent to the one of the plurality of first metallization layers and the plurality of second metallization layers to a first contact on a second side of the stiffening layer.

In a further exemplary aspect, an IC package is disclosed. The IC package includes a first package substrate and an IC comprising a circuit layer, a plurality of first metallization layers disposed on a first side of the circuit layer and coupled to the circuit layer, and a plurality of second metallization layers disposed on a second side of the circuit layer opposite to the first side and coupled to the circuit layer. The IC also includes a stiffening layer disposed on one of the plurality of first metallization layers and the plurality of second metallization layers and a first via extending through the stiffening layer from a first side of the stiffening layer adjacent to the one of the plurality of first metallization layers and the plurality of second metallization layers to a first contact on a second side of the stiffening layer, wherein the first contact is coupled to the first package substrate.

### BRIEF DESCRIPTION OF THE DRAWINGS

FIG. 1 is a cross-sectional side view of an integrated circuit (IC) package including an IC with first metallization layers on a first side coupled to a stiffening layer and a package substrate and second metallization layers on a second side coupled to a second IC in a stack;

FIG. 2 is an IC such as the IC in the IC package in FIG. 1 having a stiffening layer on a back side of a circuit layer with vias through the stiffening layer to couple second metallization layers to first external contacts and optionally second external contacts to couple second metallization layers to external circuits;

FIG. 3 is an IC having a stiffening layer on a front side of an active layer with vias through the stiffening layer to couple first metallization layers to first external contacts and optionally includes second external contacts to couple the second metallization layers to external circuits;

FIG. 4 is a flowchart of a method of fabricating an IC including first and second metallization layers on opposite sides of a circuit layer and a stiffening layer including vias coupled to one of the metallization layers, such as the ICs in FIGS. 2 and 3;

FIGS. 5A-5M are cross-sectional side views of fabrication stages of an IC, as shown in FIGS. 2 and 3 according to a method disclosed in steps of a flowchart in FIGS. 6A-6M;

FIG. 7 is a block diagram of an exemplary wireless communication device that includes radio frequency (RF) components that can include an IC including first and second metallization layers on opposite sides of a circuit layer and a stiffening layer including vias coupled to one of the metallization layers, such as the ICs in FIGS. 1-3 and 5A-5M and according to the methods illustrated in FIGS. 4 and 6A-6M; and

FIG. 8 is a block diagram of an exemplary processor-based system that can include an IC including first and second metallization layers on opposite sides of a circuit layer and a stiffening layer including vias coupled to one of the metallization layers, such as the ICs in FIGS. 1-3 and 5A-5M, and according to the methods illustrated in FIGS. 4 and 6A-6M.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed herein include integrated circuits (ICs) with two-side metallization and external stiffening layers. Related methods of fabricating an IC with two-side metallization and external stiffening layers are also disclosed. An exemplary IC includes first metallization layers on a first, front side of a circuit layer and second metallization layers on a second, back side of the circuit layer. A semiconductor substrate on the second, back side of the circuit layer can be thinned to improve access to the second, back side of semiconductor devices in the circuit layer. In this regard, the second metallization layers can provide increased interconnection between semiconductor devices in the circuit layer and may provide increased access to the circuit layer from external contacts for data, control, and power signals. However, thinning a semiconductor substrate including the circuit layer may significantly reduce structural rigidity needed for processing. Thus, the exemplary IC also includes a stiffening layer on one of the first metallization layers and the second metallization layers and first vias extending through the stiffening layer to first external contacts. The stiffening layer provides structural rigidity to reduce mechanical and electrical failures caused by the flexing of the circuit layer during, for example, manufacturing processes. In some examples, the first metallization layers include front side metallization layers and the second metallization layers include back side power rails and back side metallization layers. In some examples, the IC also includes second external contacts on the metallization layers opposite to the stiffening layer. In this regard, electrical connections between the first contacts and the second contacts may be provided, and the IC may be employed as a bottom or intermediate IC in a stack of ICs on a package substrate in an IC package.

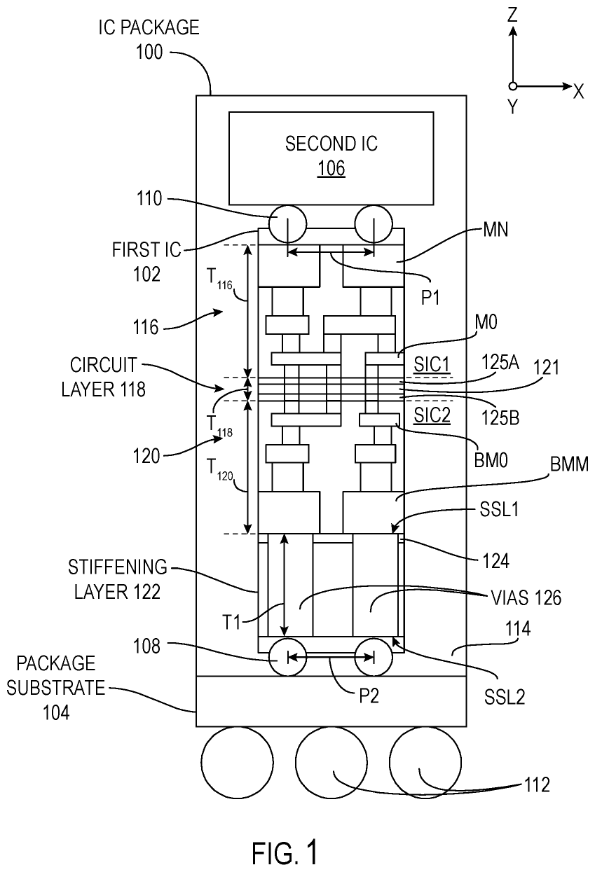

In this regard, FIG. 1 is a cross-sectional side view of an exemplary IC package 100 including a first IC 102 on a package substrate 104 and a second IC 106 on the first IC 102. The first IC 102 is coupled to the package substrate 104 through first contacts 108. The second IC 106 is coupled to the first IC 102 through second contacts 110 and may be coupled to the package substrate 104 through the first IC 102. In this manner, both the first IC 102 and the second IC 106 may be coupled to package contacts 112 on the package substrate 104, providing electrical connections from the first IC 102 and the second IC 106 to external circuits (not shown). In this example, an encapsulant 114 (e.g., a polymer) is disposed over the first IC 102 and the second IC 106 for protection (e.g., mechanical and/or chemical) from the environment. It should be understood that the illustration of the IC package 100 is for purposes of explanation only and is not intended to be to scale or complete. In addition, only portions of the first IC 102, the second IC 106, and the package substrate 104 may be shown in FIG. 1.

The first IC 102 includes a plurality of first metallization layers 116 disposed on a first, front side SIC1 of a circuit layer 118 and coupled to the circuit layer 118. The circuit layer 118 includes a semiconductor layer 121 including devices (not shown), such as transistors, that can be electrically coupled to form circuits that provide a functionality of the first IC 102.

The devices in the circuit layer 118 may include memory devices, analog devices, and/or digital logic devices for sequential logic and/or combinational logic. Any of such devices may include transistors formed in a semiconductor substrate. The first IC 102 also includes a plurality of second metallization layers 120 on a second, back side SIC2 of the circuit layer 118 opposite to the first side SIC1 and coupled to the circuit layer 118. The circuit layer 118 may be initially formed on a surface of the semiconductor substrate, most of which is removed by thinning (e.g., back grinding), leaving the circuit layer 118 comprising a semiconductor layer including active circuit devices. The semiconductor is thinned to make the circuit layer 118 more accessible from the back side SIC2.

The circuit layer 118 may also include first isolation layer 125A and a second isolation layer 125B provided on opposite sides of the semiconductor layer 121 to provide electrical isolation prior to formation of the first metallization layers 116 and second metallization layers 120. The first and second isolation layers may be formed of an inter-layer dielectric (ILD) material, an inter-metal dielectric (IMD) material, or a shallow trench isolation (STI) material that provides electrical isolation. In some examples, the semiconductor layer 121 may have a thickness T₁₁₈ in a first direction (e.g., in the Z-axis direction) of less than 10 microns and may be in a range of less than 1 micron down to one-tenth (0.1) of a micron (μm). The first metallization layers 116 have a thickness T₁₁₆ in the first direction in the range of 1.0 to 5.0 microns (μm), and the second metallization layers 120 have a thickness T₁₂₀ in the first direction in the range of 1.0 to 5.0 microns, for example. In this manner, data signals, control signals, and/or power signals may be transmitted to and from the circuit layer 118 through either the first metallization layers 116 or the second metallization layers 120. In some examples, a signal in the first metallization layers 116 may be coupled through the circuit layer 118 to the second metallization layers 120. In some examples, the devices in the circuit layer 118 may be coupled to one or both of the first metallization layers 116 and the second metallization layers 120. The circuit layer 118 may include semiconductor material sandwiched between dielectric material on the front side SIC1 and the back side SIC2.

However, thinning the circuit layer 118 as described above reduces the structural integrity of the circuit layer 118, causing it to be too weak for fabrication processes, such as transfer by an automated pick and place machine. To provide a desired level of structural rigidity to the first IC 102, a stiffening layer 122 is disposed on the second metallization layers 120 on the back side SIC2. The stiffening layer 122 provides structural rigidity to the IC 102 to reduce mechanical or electrical failures due to flexing during manufacturing processes. The stiffening layer 122 also provides a thermal reservoir to moderate fluctuations in temperature due to changes in activity (e.g., heat generation) in the circuit layer 118.

In other examples, as discussed below, the stiffening layer 122 may be disposed on and coupled to the first metallization layers 116 on the front side SIC1. The stiffening layer 122 may be any appropriate material, such as a semiconductor substrate (e.g., silicon). In the example of a silicon substrate, the stiffening layer 122 may have a thickness T1 of at least twenty (20) microns (μm) and may be in a range of 20 to one hundred (100) microns (μm). Thus, the thickness T1 of the stiffening layer 122 may be at least four (4) times the combined thickness T₁₁₆ of the thickness T₁₁₆ of the first metallization layers, the thickness T₁₁₈ of the circuit layer 118, and the thickness T₁₂₀ of the second metallization layers. Since the stiffening layer 122 may be a semiconductor material, such as silicon, a film 124 is provided between the stiffening layer 122 and the second metallization layers 120. The film 124 may be an oxide film, for example.

The first IC 102 includes vertical interconnect accesses (vias) 126 extending through the stiffening layer 122 to couple the second metallization layers 120 to the first contacts 108 disposed on the stiffening layer 122. In this manner, the vias 126 and the first contacts 108 couple the circuit layer 118 to the package substrate 104. The vias 126 may be through-silicon vias (TSVs) that extend from a first side SSL1 of the stiffening layer 122 adjacent to the second metallization layers 120 to a first contact 108 on a second side SSL2 of the stiffening layer 122. The vias 126 may be formed of at least one of copper, tungsten, and other conductive metals or materials. The vias 126 may each have a height-to-width aspect ratio (e.g., Z-axis direction to X-axis direction) in the range from five to one (5:1) up to ten to one (10:1). On the front side SIC1, the first metallization layers 116 of the first IC 102 are coupled to the second IC 106 by the second contacts 110. The stiffening layer 122 provides a space in which power distribution network capacitors (not shown) may be formed. For example, trench capacitors (not shown) may be formed in either the first side SSL1 or the second side SSL2 of the stiffening layer 122.

The first metallization layers 116 include metal layers M0-MN, where the metal layer M0 is closest to the circuit layer 118 on the first side SIC1, and the metal layers M1-MN are formed on the metal layer M0 with the metal layer MN farthest from the circuit layer 118. Dimensions of the metal layers M0-MN in a width direction (X-axis direction or Y-axis direction) and a height direction (Z-axis direction) are smallest in the metal layer M0 and increase to the largest in the metal layer MN. The metal layer MN is compatible with a pitch PI of the second contacts 110. The metal layers M0-MN are separated and electrically isolated from each other by dielectric material 132, which may be an ILD, an IMD, or an STI material.

Similarly, the second metallization layer 120 includes bottom metal layers BM0-BMM, with the bottom metal layer BM0 being closest to the back side SIC2 of the circuit layer 118 and having the smallest width and height dimensions. The bottom metal layer BMM is farthest from the circuit layer 118 and has the largest width and height dimensions of any of the bottom metal layers BM0-BMM, which are compatible with a pitch P2 of the first contacts 108. The bottom metal layers BM0-BMM are also isolated from each other by an ILD, IMD, or STI material.

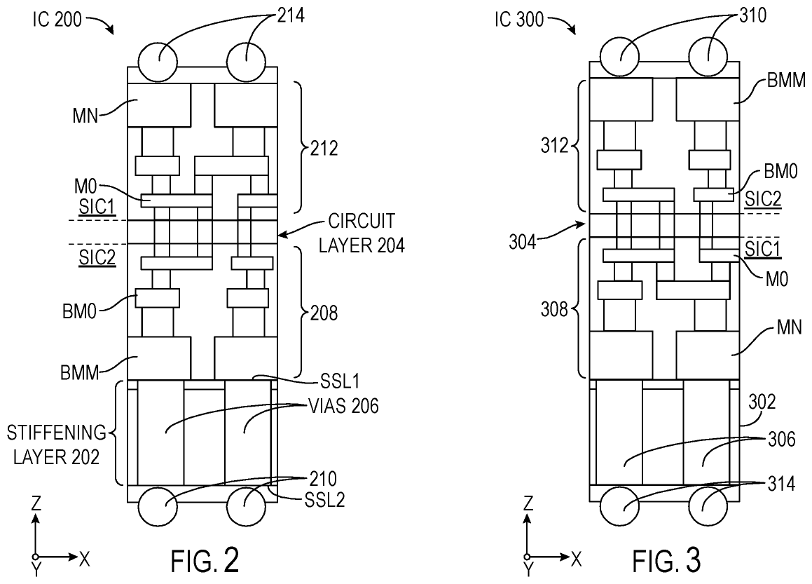

FIG. 2 is an illustration of an IC 200, which may be the first IC 102 in FIG. 1, including a stiffening layer 202 on a back side SIC2 of a circuit layer 204 with vias 206 extending through the stiffening layer 202 to couple bottom metal layers BM0-BMM of second metallization layers 208 to first external contacts 210. The IC 200 includes first metallization layers 212 including metal layers M0-MN, which may be optionally coupled to second external contacts 214. In some examples, the IC 200 may not have a second IC (such as the second IC 106 in FIG. 1) disposed on one side. In such examples, the IC 200 may be coupled to external circuits (not shown) only through the first external contacts 210, such as to a package substrate as in FIG. 1. In such examples, the first metallization layer 212 may be employed for interconnection of devices in the circuit layer 204. In other examples, including second external contacts 214 on the first metallization layers 212, one or more additional ICs, or another package substrate (not shown) may be coupled to the first side SIC1 of the IC 200 and through the IC 200 to a package substrate and external circuits (not shown). As the first IC 102 was described in detail above and is substantially the same as the IC 200 in FIG. 2, the IC 200 will not be described further here.

FIG. 2 is provided here for purposes of comparison to the IC 300 in FIG. 3. The IC 300 has a stiffening layer 302 on a front side SIC1 of a circuit layer 304 and includes vias 306 to couple first metallization layers 308 to second contacts 310. The IC 300 also includes second metallization layers 312 that are optionally coupled to first contacts 314.

The IC 300 in FIG. 3 differs from the IC 200 in FIG. 2 only with respect to a location of the stiffening layer 302. In the IC 300, the stiffening layer 302 is coupled to the first metallization layers 308 on the front side SIC1 of the circuit layer 304 rather than on the second metallization layers 312 on the back side SIC2, as shown in FIG. 2. In such example, bottom metal layers BM0-BMM of the second metallization layers 312 may be used for interconnection of devices (not shown) in the circuit layer 304 and the metal layers M0-MN may be used for both interconnection of devices within the circuit layer 304 and to connect the circuit layer 304 to the first contacts 314 by way of the vias 306 through the stiffening layer 302.

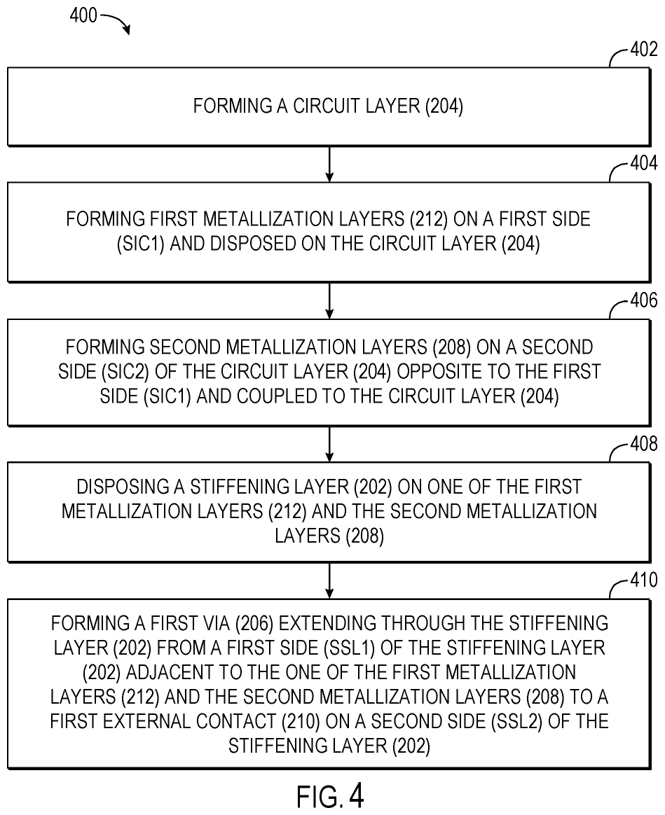

Fabrication processes can be employed to fabricate an IC including a stiffening layer on a first side of a circuit layer with vias extending through the stiffening layer to couple metal layers of a plurality of second metallization layers to first external contacts including but not limited to the ICs 100, 200, and 300 in FIGS. 1-3. In this regard, FIG. 4 is a flowchart illustrating an exemplary fabrication process 400 of fabricating an IC 200 including a stiffening layer 202 on a back side SIC2 of a circuit layer 204 with vias 206 extending through the stiffening layer 202 to couple bottom metal layers BM0-BMM of second metallization layers 208 to first external contacts 210. The fabrication process 400 in FIG. 4 is discussed with regard to the IC 200 in FIG. 2, but note that the fabrication process 400 in FIG. 4 is not limited to fabricating an IC including a stiffening layer 202 on a back side SIC2 of a circuit layer 204 with vias 206 extending through the stiffening layer 202 to couple bottom metal layers BM0-BMM of second metallization layers 208 to first external contacts 210 as shown in FIG. 2.

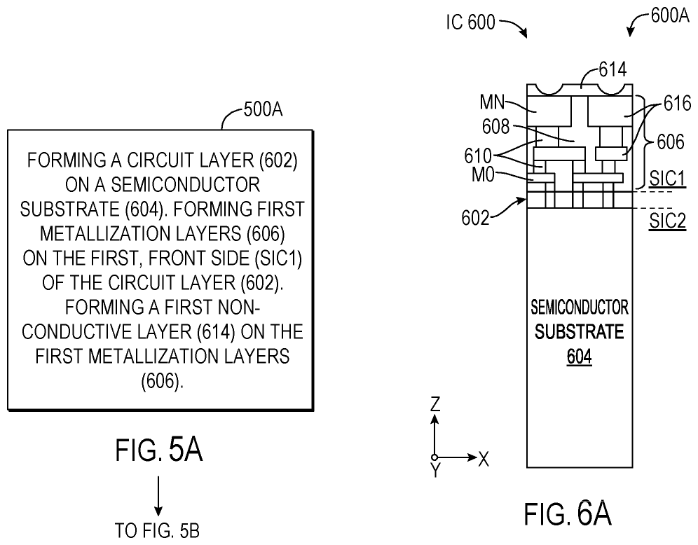

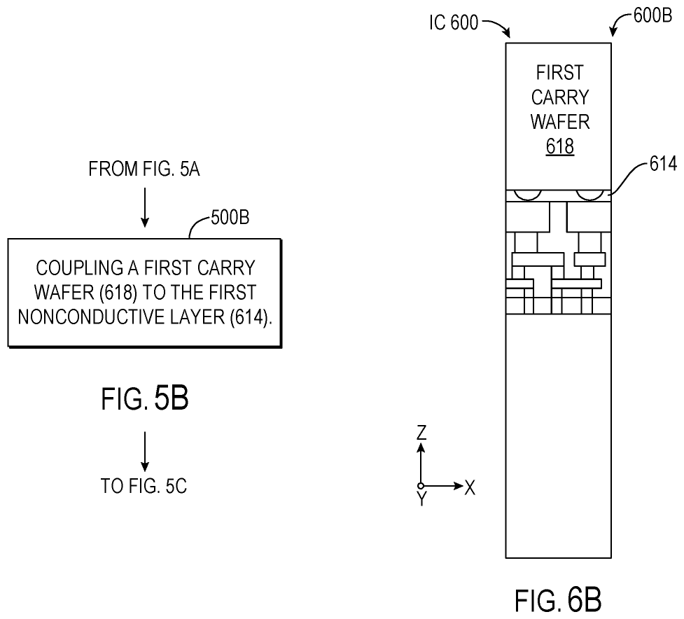

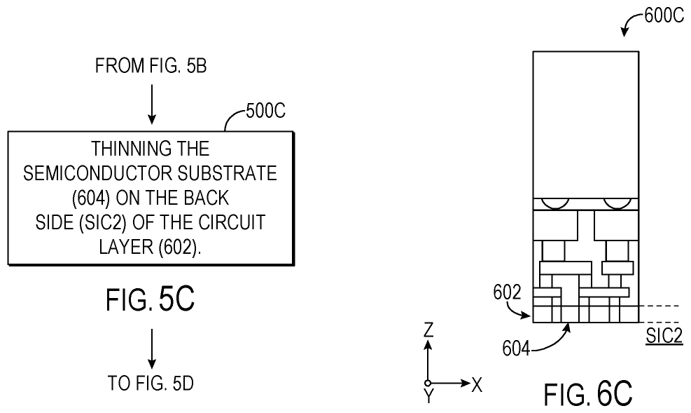

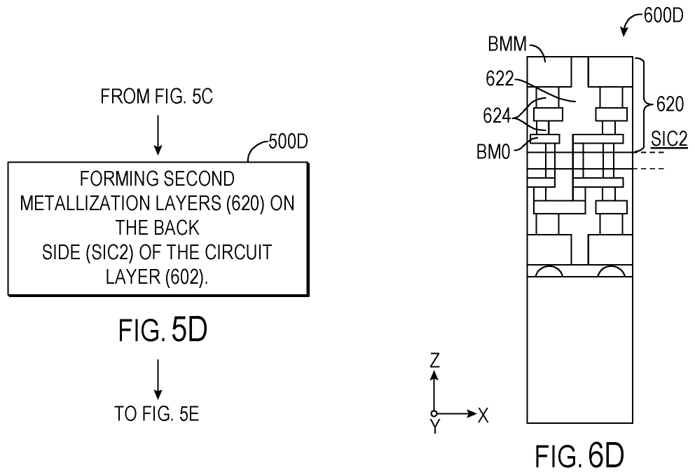

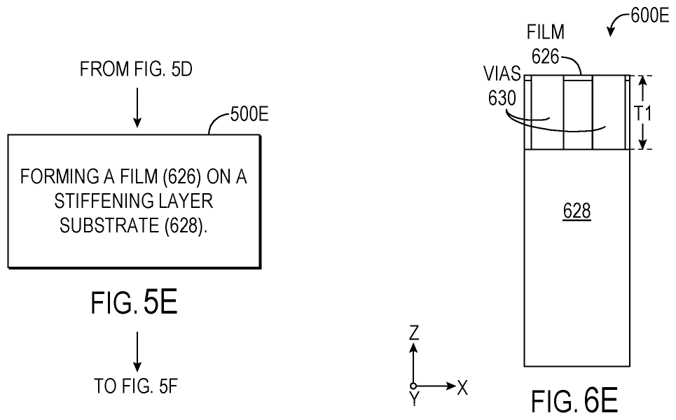

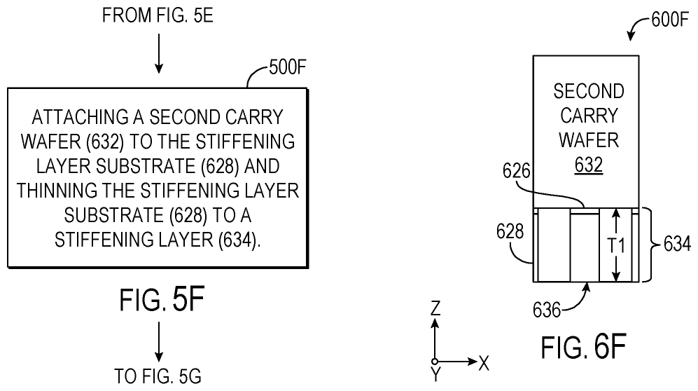

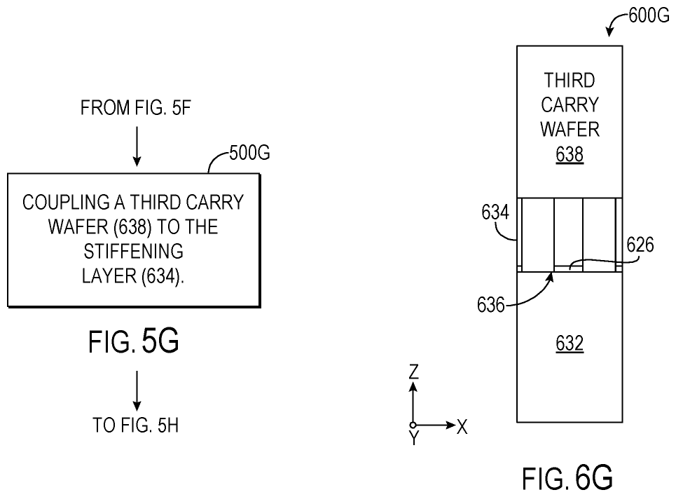

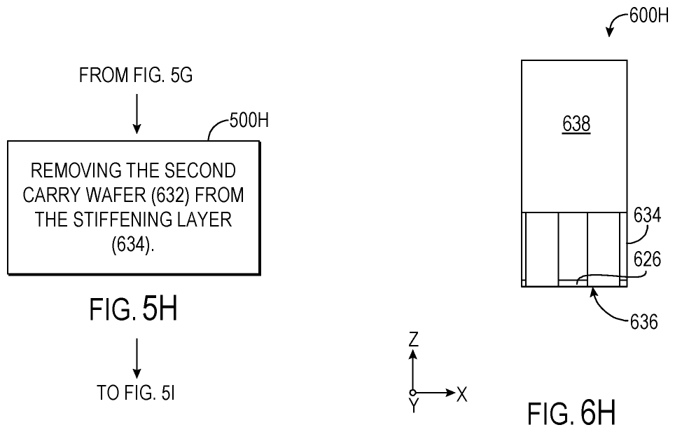

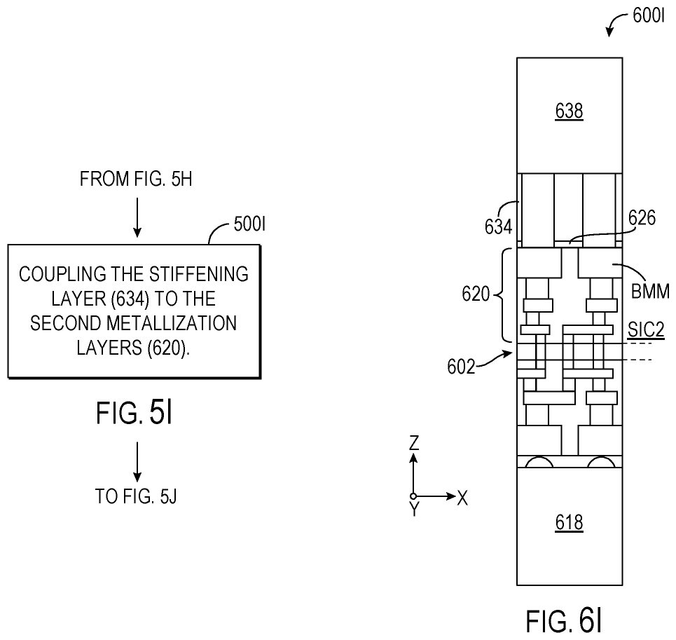

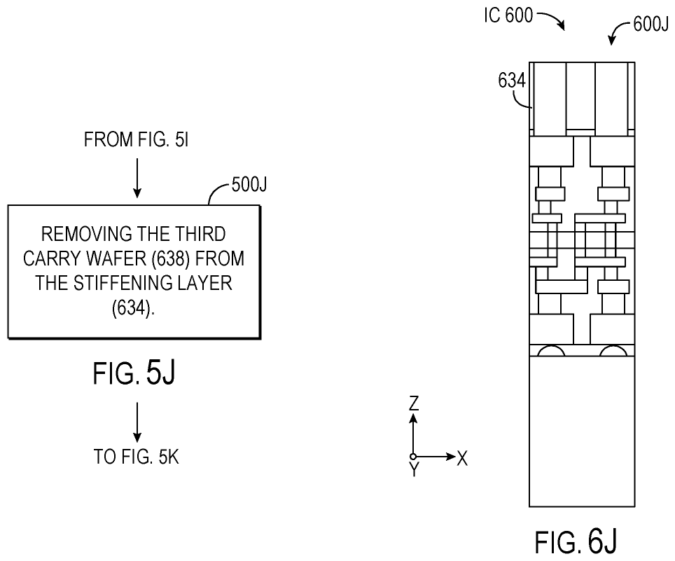

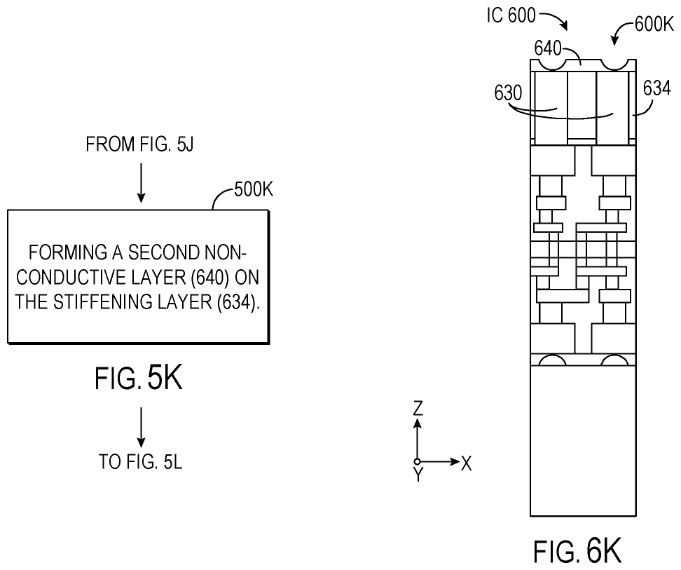

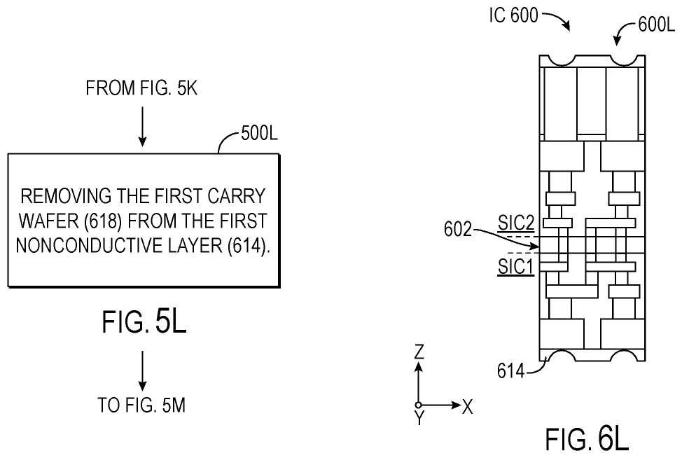

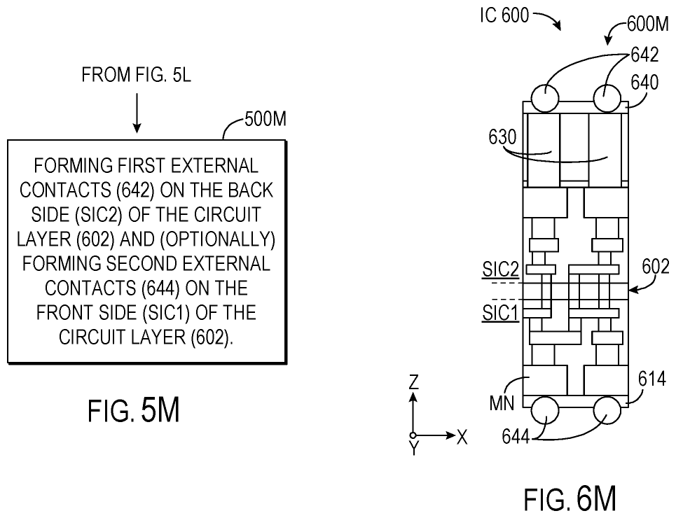

In this regard, exemplary steps in fabricating the IC 200 in FIG. 2 include forming a circuit layer 204 (block 402 in FIG. 4), forming first metallization layers 212 on the first side SIC1 and disposed on the circuit layer 204 (block 404), and forming second metallization layers 208 on a second side SIC2 of the circuit layer 204 opposite to the first side SIC1 and coupled to the circuit layer 204 (block 406). The method 400 further includes disposing a stiffening layer 202 on one of the first metallization layers 212 and the second metallization layers 208 (block 408) and forming a first via 206 extending through the stiffening layer 202 from a first side SSL1 of the stiffening layer 202 adjacent to the one of the first metallization layers 212 and the second metallization layers 208 to a first external contact 210 on a second side SSL2 of the stiffening layer 202 (block 410). Other fabrication processes can also be employed to fabricate the IC 200 including a stiffening layer 202 on a back side SIC2 of a circuit layer 204 with vias 206 extending through the stiffening layer 202 to couple bottom metal layers BM0-BMM of second metallization layers 208 to first external contacts 210 including but not limited to the ICs 102, 200, and 300 in FIGS. 1-3. In this regard, FIGS. 5A-5M are a flowchart illustrating another exemplary fabrication process 500 of fabricating an IC 200 including a stiffening layer 202 on a back side SIC2 of a circuit layer 204 with vias 206 extending through the stiffening layer 202 to couple bottom metal layers BM0-BMM of second metallization layers 208 to first external contacts 210 including but not limited to the ICs 102, 200, and 300 in FIGS. 1-3. FIGS. 6A-6M are exemplary fabrication stages 600A-600M during fabrication of the IC 200 including a stiffening layer 202 on a back side SIC2 of a circuit layer 204 with vias 206 extending through the stiffening layer 202 to couple bottom metal layers BM0-BMM of second metallization layers 208 to first external contacts 210, according to the fabrication process 500 in FIGS. 5A-5M. The fabrication process 500 in FIGS. 5A-5M will now be discussed in conjunction with the exemplary fabrication stages 600A-600M in FIGS. 6A-6M using the IC 200 in FIG. 2 as an example. However, note that the fabrication process 500 in FIGS. 5A-5M represented by the fabrication stages 600A-600M in FIGS. 6A-6M could also be applicable to fabricate the IC 102 in FIG. 1 and the IC 300 in FIG. 3 as well.

In this regard, as shown in the fabrication stage 500A in FIG. 5A, a first step in the fabrication process includes forming a circuit layer 502 on a semiconductor substrate 504. As noted above, the circuit layer 602 includes devices such as transistors coupled in circuits that provide functionality of the IC 600. The method 500 further includes forming first metallization layers 606 on the first, front side SIC1 of the circuit layer 602. The first metallization layers 606 include metal layers M0-MN separated by dielectric material 608. Forming the first metallization layers 606 includes repeating a sequence including forming a layer of a dielectric material 608, forming vias 610 through the layer of dielectric material 608, and forming one of the metal layers M0-MN. Such sequence is repeated until metal layer MN is formed. Step 500A also includes forming a first non-conductive (e.g., oxide) layer 614 on the first metallization layers 606, in particular the metal layer MN. Each of the metal layers MO-MN includes interconnects 616 that extend parallel to the circuit layer 602 (e.g., in a plane including the X-axis and the Y-axis). In this regard, the vias 610 extend between metal layers M0-MN in a first direction or “vertically” (e.g., in the Z-axis direction) and the interconnects 616 extend in second and third directions (e.g., the X-axis and Y-axis directions) or “horizontally”, which are orthogonal to each other and to the first direction.

FIG. 6B is the cross-sectional side view in the fabrication stage 600B of fabricating the IC 600 according to step 500B of the method 500 in FIG. 5B. The step 500B includes coupling a first carry wafer 618 to the first non-conductive layer 614.

FIG. 6C is the cross-sectional side view in the fabrication stage 600C of fabricating the IC 600 according to step 500C of the method 500 in FIG. 5C. The step 500C includes thinning the semiconductor substrate 604 on the back side SIC2 of the circuit layer 602. The semiconductor substrate is thinned to the back sides of devices in the circuit layer 602.

FIG. 6D is the cross-sectional side view in the fabrication stage 600D of fabricating the IC 600 according to step 500D of the method 500 in FIG. 5D. The step 500D includes forming second metallization layers 620 on the back side SIC2 of the circuit layer 602 (shown inverted from FIG. 6C). Forming the second metallization layers 620 includes repeating a sequence including forming a layer of a dielectric material 622, forming vias 624 through the layer of dielectric material 622, and forming one of the bottom metal layers BM0-BMM. Such sequence is repeated until bottom metal layer BMM is formed. The bottom metal layers BM0-BMM include horizontal interconnects coupled in the vertical direction by the vias 624.

FIG. 6E is the cross-sectional side view in the fabrication stage 600E of fabricating the IC 600 according to step 500E of the method 500 in FIG. 5E. The step 500E includes forming a film (e.g., oxide) 626 on a stiffening layer substrate 628, which may be a semiconductor (e.g., silicon) substrate, forming vias 630 (e.g., TSVs) through the film 626 and through a first thickness T1 of the stiffening layer substrate 628.

FIG. 6F is the cross-sectional side view in the fabrication stage 600F of fabricating the IC 600 according to step 500F of the method 500 in FIG. 5F. The step 500F includes attaching a second carry wafer 632 to the stiffening layer substrate 628 and thinning the stiffening layer substrate 628 to a stiffening layer 634. In particular, the second carry wafer 632 is coupled to the film 626 and the back side of the stiffening layer substrate 628 is thinned by mechanical grinding and/or chemical means. The stiffening layer substrate 628 is thinned to the thickness T1, leaving the stiffening layer 634 having the thickness T1 and a surface 636.

FIGS. 6G and 6H are the cross-sectional side views in the fabrication stages 600G and 600H of fabricating the IC 600 according to steps 500G and 500H of the method 500 in FIGS. 5G and 5H. The steps 500G include coupling a third carry wafer 638 to the stiffening layer 634, as shown in FIG. 6G, and removing the second carry wafer 632 from the stiffening layer 634, as shown in FIG. 6H. The third carry wafer 638 is coupled to the surface 636 of the stiffening layer 634. Removing the second carry wafer 632 exposes the film 626 on the stiffening layer 634.

FIG. 6I is the cross-sectional side view in the fabrication stage 600I of fabricating the IC 600 according to step 500I of the method 500 in FIG. 5I. The step 500I includes coupling the stiffening layer 634 (shown in FIG. 6H) to the second metallization layers 620 (shown in FIG. 6D). In particular, while the stiffening layer 634 is attached to the third carry wafer 638, the film 626 is coupled to the bottom metal layer BMM of the second metallization layers 620 on the back side SIC2 of the circuit layer 602, which is attached to the first carry wafer 618.

FIGS. 6J and 6K are the cross-sectional side views in the fabrication stages 600J and 600K of fabricating the IC 600 according to steps 500J and 500K of the method 500 in FIGS. 5J and 5K. The step 500J includes removing the third carry wafer 638 (see FIG. 6I) from the stiffening layer 634 and step 500K includes forming a second non-conductive layer 640 on the stiffening layer 634. The second non-conductive layer 640 may be patterned to expose the vias 630 that were formed in the stiffening layer 634.

FIGS. 6L and 6M are the cross-sectional side views in the fabrication stages 600L and 600M of fabricating the IC 600 according to steps 500L and 500M of the method 500 in FIGS. 5L and 5M. The step 500L includes removing the first carry wafer 618 (see FIG. 6K) from the first non-conductive layer 614, which is on the front side SIC1 of the circuit layer 602. Step 500M includes forming first external contacts 642 on the back side SIC2 of the circuit layer 602 and (optionally) forming second external contacts 644 on the front side SIC1 of the circuit layer 602. The first external contacts 642 are formed on the patterned second non-conductive layer 640 and coupled to the exposed vias 630. Similarly, the second contacts 644 are formed on the first non-conductive layer 614, which is also patterned, and coupled to the metal layer MN of the first metallization layers 606.

Electronic devices that include ICs including first and second metallization layers on opposite sides of a circuit layer and a stiffening layer including vias coupled to one of the metallization layers, such as the ICs in FIGS. 1-3 and 6A-6M and according to, but not limited to, any of the exemplary fabrication processes in FIGS. 4 and 5A-5M, and according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

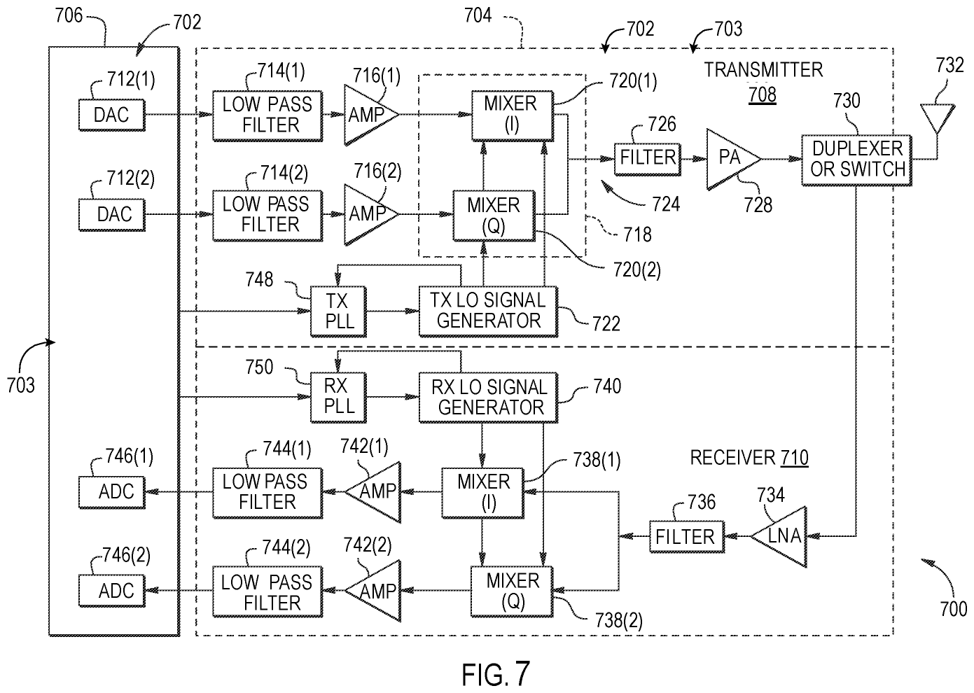

In this regard, FIG. 7 illustrates a block diagram of an exemplary wireless communications device 700 that includes radio frequency (RF) components formed from one or more ICs 702, wherein any of the ICs 702 can include first and second metallization (backside power rail and metallization) layers on opposite sides of a circuit layer and a stiffening layer including vias coupled to one of the metallization layers, such as the ICs in FIGS. 1-3 and 6A-6M and according to, but not limited to, any of the exemplary fabrication processes in FIGS. 4 and 5A-5M, and according to any aspects disclosed herein. The wireless communications device 700 may include or be provided as examples in any of the above-referenced devices. As shown in FIG. 7, the wireless communications device 700 includes a transceiver 704 and a data processor 706. The data processor 706 may include a memory to store data and program codes. The transceiver 704 includes a transmitter 708 and a receiver 710, which support bi-directional communications. In general, the wireless communications device 700 may include any number of transmitters 708 and/or receivers 710 for any number of communication systems and frequency bands. All or a portion of the transceiver 704 may be implemented on one or more analog ICs, RF ICs (RFICs), mixed-signal ICs, etc.

The transmitter 708 or the receiver 710 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals from a TX LO signal generator 722 through mixers 720(1), 720(2) to provide an upconverted signal 724. A filter 726 filters the upconverted signal 724 to remove undesired signals caused by the frequency upconversion and noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

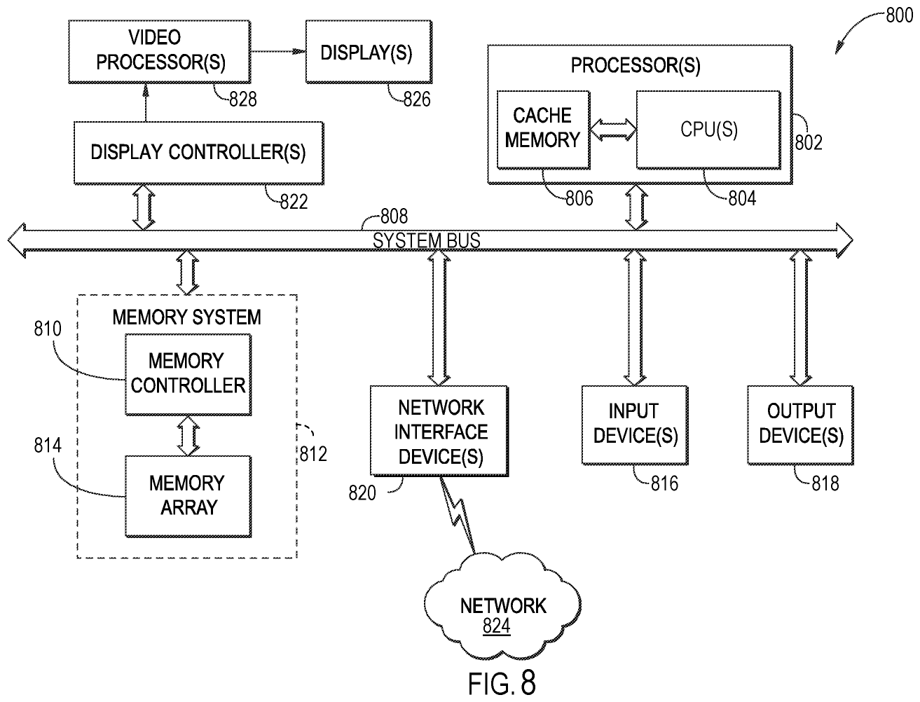

FIG. 8 illustrates a block diagram of an example of a processor-based system 800 that can employ ICs including first and second metallization layers on opposite sides of a circuit layer and a stiffening layer including vias coupled to one of the metallization layers, such as the ICs in FIGS. 1-3 and 6A-6M and according to, but not limited to, any of the exemplary fabrication processes in FIGS. 4 and 5A-5M. In this example, the processor-based system 800 includes one or more central processor units (CPUs) 802. which may also be referred to as CPU or processor cores, each including one or more processors 804. The CPU(s) 802 may have cache memory 806 coupled to the processor(s) 804 for rapid access to temporarily stored data. The CPU(s) 802 is coupled to a system bus 808 and can intercouple master and secondary device devices included in the processor-based system 800. As is well known, the CPU(s) 802 communicates with these other devices by exchanging address, control, and data information over the system bus 808. For example, the CPU(s) 802 can communicate bus transaction requests to a memory controller 810 as an example of a slave device. Although not illustrated in FIG. 8, multiple system buses 808 could be provided wherein each system bus 808 constitutes a different fabric.

Other master and slave devices can be connected to the system bus 808. As illustrated in FIG. 8, these devices can include a memory system 812 that includes the memory controller 810 and one or more memory arrays 814, one or more input devices 816, one or more output devices 818, one or more network interface devices 820, and one or more display controllers 822, as examples. The input device(s) 816 can include any type of input device, including, but not limited to, input keys, switches, voice processors, etc. The output device(s) 818 can include any type of output device, including, but not limited to, audio, video, other visual indicators, etc. The network interface device(s) 820 can be any device configured to allow an exchange of data to and from a network 824. The network 824 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 820 can be configured to support any type of communications protocol desired.

The CPU(s) 802 may also be configured to access the display controller(s) 822 over the system bus 808 to control information sent to one or more displays 826. The display controller(s) 822 sends information to the display(s) 826 to be displayed via one or more video processors 828, which process the information to be displayed into a format suitable for the display(s) 826. The display(s) 826 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. An integrated circuit (IC), comprising:
   a circuit layer;
   a plurality of first metallization layers disposed on a first side of the circuit layer and coupled to the circuit layer;
   a plurality of second metallization layers disposed on a second side of the circuit layer opposite to the first side and coupled to the circuit layer;
   a stiffening layer disposed on one of the plurality of first metallization layers and the plurality of second metallization layers; and
   a first via extending through the stiffening layer to couple the one of the plurality of first metallization layers and the plurality of second metallization layers to a first contact on the stiffening layer.
2. The IC of clause 1, wherein the circuit layer comprises:
   a semiconductor layer comprising devices;
   a first isolation layer disposed on the devices on the first side of the circuit layer; and
   a second isolation layer disposed on the second side of the circuit layer.
3. The IC of clause 2, wherein the first isolation layer and the second isolation layer comprise one of inter-layer dielectric (ILD) material, inter-metal dielectric (IMD) material, and shallow trench isolation (STI) material.
4. The IC of any of clause 1 to clause 3, wherein a thickness of the circuit layer is less than two (2) microns (μm).
5. The IC of any of clause 1 to clause 4, wherein the stiffening layer has a thickness in a range of twenty (20) to one hundred (100) microns (μm).
6. The IC of any of clause 1 to clause 5, wherein a thickness of the stiffening layer is at least ten (10) times a thickness of the circuit layer.
7. The IC of clause 2 or clause 3, further comprising back side vias extending from the semiconductor layer and through the second isolation layer to couple the devices to the plurality of second metallization layers.
8 The IC of clause 2, clause 3, or clause 7, further comprising front side vias extending through the first isolation layer to couple the devices to the plurality of first metallization layers.
9. The IC of any of clause 1 to clause 8, wherein a height-to-width ratio of the first via is in a range of five to one (5:1) to ten to one (10:1).
10. The IC of any of clause 1 to clause 9, wherein a thickness of a first plurality of metal layers in the plurality of first metallization layers is in a range of 1.0 to 3.0 microns (μm).
11. The IC of any of clause 1 to clause 10, wherein a thickness of a second plurality of metal layers in the plurality of second metallization layers is in a range of 1.0 to 3.0 microns (μm).
12. The IC of any of clause 1 to clause 11, wherein the stiffening layer comprises silicon.
13. The IC of any of clause 1 to clause 12, wherein the stiffening layer comprises a trench capacitor coupled to the first via.
14. The IC of any of clause 1 to clause 13, further comprising a second contact coupled to the other one of the plurality of first metallization layers and the plurality of second metallization layers and configured to couple the circuit layer to an external circuit.
15. The IC of any of clause 1 to clause 14, integrated into an integrated circuit package.
16. The IC of any of clause 1 to clause 15, integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
17. A method of fabricating an integrated circuit (IC), the method comprising:
   forming a circuit layer;
   forming a plurality of first metallization layers on a first side of the circuit layer;
   forming a plurality of second metallization layers on a second side of the circuit layer opposite to the first side;
   disposing a stiffening layer on one of the plurality of first metallization layers and the plurality of second metallization layers; and
   forming a first via extending through the stiffening layer from a first side of the stiffening layer adjacent to the one of the plurality of first metallization layers and the plurality of second metallization layers to a first contact on a second side of the stiffening layer.
18. An integrated circuit (IC) package comprising:
   a first package substrate; and
   an IC comprising:
      a circuit layer;
      a plurality of first metallization layers disposed on a first side of the circuit layer and coupled to the circuit layer;
      a plurality of second metallization layers disposed on a second side of the circuit layer opposite to the first side and coupled to the circuit layer;
      a stiffening layer disposed on one of the plurality of first metallization layers and the plurality of second metallization layers; and
      a first via extending through the stiffening layer from a first side of the stiffening layer adjacent to the one of the plurality of first metallization layers and the plurality of second metallization layers to a first contact on a second side of the stiffening layer,
wherein the first contact is coupled to the first package substrate.

19. The IC package of clause 18, further comprising:
a second contact coupled to the other one of the plurality of first metallization layers and the plurality of second metallization layers; and
a second IC coupled to the second contact.

What is claimed is:

1. An integrated circuit (IC), comprising:
a circuit layer;
a plurality of first metallization layers disposed on a first side of the circuit layer and coupled to the circuit layer;
a plurality of second metallization layers disposed on a second side of the circuit layer opposite to the first side and coupled to the circuit layer;
a stiffening layer disposed on one of the plurality of first metallization layers and the plurality of second metallization layers; and
a first via extending through the stiffening layer to couple the one of the plurality of first metallization layers and the plurality of second metallization layers to a first contact on the stiffening layer.

2. The IC of claim 1, wherein the circuit layer comprises:
a semiconductor layer comprising devices;
a first isolation layer disposed on the devices on the first side of the circuit layer; and
a second isolation layer disposed on the second side of the circuit layer.

3. The IC of claim 2, wherein the first isolation layer and the second isolation layer comprise one of inter-layer dielectric (ILD) material, inter-metal dielectric (IMD) material, and shallow trench isolation (STI) material.

4. The IC of claim 1, wherein a thickness of the circuit layer is less than two (2) microns (μm).

5. The IC of claim 1, wherein the stiffening layer has a thickness in a range of twenty (20) to one hundred (100) microns (μm).

6. The IC of claim 1, wherein a thickness of the stiffening layer is at least ten (10) times a thickness of the circuit layer.

7. The IC of claim 2, further comprising back side vias extending from the semiconductor layer and through the second isolation layer to couple the devices to the plurality of second metallization layers.

8. The IC of claim 2, further comprising front side vias extending through the first isolation layer to couple the devices to the plurality of first metallization layers.

9. The IC of claim 1, wherein a height-to-width ratio of the first via is in a range of five to one (5:1) to ten to one (10:1).

10. The IC of claim 1, wherein a thickness of a first plurality of metal layers in the plurality of first metallization layers is in a range of 1.0 to 3.0 microns (μm).

11. The IC of claim 1, wherein a thickness of a second plurality of metal layers in the plurality of second metallization layers is in a range of 1.0 to 3.0 microns (μm).

12. The IC of claim 1, wherein the stiffening layer comprises silicon.

13. The IC of claim 1, wherein the stiffening layer comprises a trench capacitor coupled to the first via.

14. The IC of claim 1, further comprising a second contact coupled to the other one of the plurality of first metallization layers and the plurality of second metallization layers and configured to couple the circuit layer to an external circuit.

15. The IC of claim 1, integrated into an integrated circuit package.

16. The IC of claim 1, integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

17. A method of fabricating an integrated circuit (IC), the method comprising:
forming a circuit layer;
forming a plurality of first metallization layers on a first side of the circuit layer;
forming a plurality of second metallization layers on a second side of the circuit layer opposite to the first side;
disposing a stiffening layer on one of the plurality of first metallization layers and the plurality of second metallization layers; and
forming a first via extending through the stiffening layer from a first side of the stiffening layer adjacent to the one of the plurality of first metallization layers and the plurality of second metallization layers to a first contact on a second side of the stiffening layer.

18. An integrated circuit (IC) package comprising:
a first package substrate; and
an IC comprising:
a circuit layer;
a plurality of first metallization layers disposed on a first side of the circuit layer and coupled to the circuit layer;
a plurality of second metallization layers disposed on a second side of the circuit layer opposite to the first side and coupled to the circuit layer;
a stiffening layer disposed on one of the plurality of first metallization layers and the plurality of second metallization layers; and
a first via extending through the stiffening layer from a first side of the stiffening layer adjacent to the one of the plurality of first metallization layers and the plurality of second metallization layers to a first contact on a second side of the stiffening layer,
wherein the first contact is coupled to the first package substrate.

19. The IC package of claim 18, further comprising:
a second contact coupled to the other one of the plurality of first metallization layers and the plurality of second metallization layers; and
a second IC coupled to the second contact.
